(19) United States
(12) Patent Application Publication
(10) Pub. No.: US 2010/0307414 A1
(43) Pub. Date: Dec. 9, 2010

(54) Take-Up Type Vacuum Deposition Apparatus

(75) Inventors: Shin Yokoi, Kanagawa (JP); Tsunehito Nomura, Kanagawa (JP); Atsushi Nakatsuka, Kanagawa (JP); Isao Tada, Kanagawa (JP)

Correspondence Address: HARNESS, DICKEY & PIERCE, P.L.C., P.O. BOX 828, BLOOMFIELD HILLS, MI, 48303, US

(73) Assignee: ULVAC, INC., Kanagawa (JP)

(21) Appl. No.: 12/867,254

(22) PCT Filed: Apr. 14, 2008
(86) PCT No.: PCT/JP2008/057286

§ 371 Date: Aug. 12, 2010

(51) Int. Cl. C23C 14/14; C23C 14/28; C23C 14/58

(52) U.S. Cl. 118/712; 118/50.1

(57) ABSTRACT

[Object] To provide a take-up type vacuum deposition apparatus capable of preventing a thermal deformation of a base material due to charged particles leaked from a neutralization unit without an increase in size of the apparatus.

[Solving Means] A take-up type vacuum deposition apparatus according to the present invention includes a charge capturing body provided between a cooling can roller and a neutralization unit that captures charged particles floating from the neutralization unit toward the can roller. Accordingly, the charged particles leaked from the neutralization unit are prevented from reaching the can roller, which suppresses variation in a bias potential applied to the can roller for bringing it into close contact with a base material, and keeps stable electrostatic force with respect to the base material. Accordingly, adhesion force between the base material and the cooling roller can be kept stable, and thus a thermal deformation of the base material can be suppressed.

### FIELD

The present invention relates to a take-up type vacuum deposition apparatus for depositing, while cooling an insulating base material successively paid out under a reduced-pressure atmosphere by bringing the base material into close contact with a cooling roller, a metallic layer onto the base material and taking up the base material.

### BACKGROUND

There is known a take-up type vacuum vapor deposition apparatus that deposits, while winding a long material film (base material) successively paid out from a payout roller around a cooling can roller, an evaporation material from an evaporation source provided opposed to the can roller onto the base material and takes up the base material that has been subjected to the vapor deposition by a take-up roller (see, for example, Patent Document 1 below).

In the vacuum vapor deposition apparatus of this type, for preventing a thermal deformation of a base material during vapor deposition, deposition processing is carried out while the base material is cooled by being brought into close contact with a circumferential surface of a can roller. Therefore, how to secure an adhesion effect of the base material with respect to the can roller becomes important.

In this regard, in the take-up type vacuum vapor deposition apparatus disclosed in Patent Document 1, there is disclosed a method of electrostatically bringing a base material into close contact with a cooling can roller by providing an auxiliary roller that comes into contact with a deposition surface of the base material between the can roller and a take-up roller, and applying a DC current between the auxiliary roller and the can roller. Accordingly, an adhesion effect of the base material with respect to the can roller can be obtained, and thus a thermal deformation of the base material during vapor deposition is effectively prevented.

Meanwhile, in the take-up type vacuum vapor deposition apparatus having the above structure, there has been a problem that, during take-up of the base material by the take-up roller, wrinkles cause in the base material due to an influence of electric charges remaining in the base material after the vapor deposition, with the result that the base material cannot be properly taken-up. To solve this problem, there is known a method of providing a neutralization unit that neutralizes, by a plasma treatment, a base material that has been subjected to vapor deposition to remove electric charges charged to the base material by the neutralization unit before taking-up of the base material (see Patent Document 2).

Patent Document 1: Japanese Patent No. 3795518

Patent Document 2: W02006/088024

### SUMMARY

### Problems to be Solved by the Invention

However, in the vacuum vapor deposition apparatus including the neutralization unit, there is a problem that electrons and charged particles such as ions in plasma leak out from the neutralization unit, which results in variation in a bias voltage applied between the can roller and the auxiliary roller and an unstable adhesion effect of the base material with respect to the can roller.

For example, when a bias voltage is applied with the can roller and the auxiliary roller being a positive electrode and a negative electrode, respectively, a potential of the can roller is lowered by electrons floating from the neutralization unit and reached the can roller, resulting in lowering of electrostatic attractive force with respect to the base material. Accordingly, adhesion force between the can roller and the base material is lowered, which may cause a thermal deformation of the base material.

To prevent such a problem from occurring, it is contemplated to provide the neutralization unit at a position apart from the can roller as much as possible. However, this leads to an increase in size of the apparatus, as well as a smaller degree of freedom in design of the apparatus, and therefore is not a practical measure.

The present invention is made in view of the above problem, and it is an object of the present invention to provide a take-up type vacuum deposition apparatus capable of preventing a thermal deformation of a base material due to charged particles leaked from a neutralization unit without an increase in size of the apparatus.

### Means for Solving the Problems

According to an embodiment of the present invention, there is provided a take-up type vacuum deposition apparatus for depositing a metallic layer on a base material having insulation property, including a vacuum chamber, a transport mechanism, a cooling roller, a deposition means, an auxiliary roller, a voltage application means, a neutralization unit, and a charge capturing unit.

The transport mechanism transports the base material inside the vacuum chamber. The cooling roller cools the base material by coming into close contact with the base material. The deposition means is provided opposed to the cooling roller, and deposits the metallic layer on the base material. The auxiliary roller guides traveling of the base material by coming into contact with a deposition surface of the base material. The voltage application unit applies a DC voltage between the cooling roller and the auxiliary roller. The neutralization unit neutralizes the base material by a plasma treatment. The charge capturing body is provided between the cooling roller and the neutralization unit, and captures charged particles floating from the neutralization unit toward the cooling roller.

### Best Mode for Carrying Out the Invention

According to an embodiment of the present invention, there is provided a take-up type vacuum deposition apparatus for depositing a metallic layer on a base material having insulation property, including a vacuum chamber, a transport mechanism, a cooling roller, a deposition means, an auxiliary roller, a neutralization unit, and a charge capturing unit.

The transport mechanism transports the base material inside the vacuum chamber.

The cooling roller cools the base material by coming into close contact with the base material.

The deposition means is provided opposed to the cooling roller, and deposits the metallic layer on the base material.

The auxiliary roller guides traveling of the base material by coming into contact with a deposition surface of the base material.

The neutralization unit neutralizes the base material by a plasma treatment.

The charge capturing body is provided between the cooling roller and the neutralization unit, and captures charged particles flowing from the neutralization unit toward the cooling roller.

In the take-up type vacuum deposition apparatus, the charge capturing body that captures charged particles floating from the neutralizing unit toward the cooling roller is provided between the cooling roller and the neutralizing unit. The charge capturing body prevents the charged particles leaked from the neutralization unit from reaching the cooling roller to suppress variation in a potential of the cooling roller and keep stable electrostatic force with respect to the base material. Accordingly, adhesion force between the base material and the cooling roller can be kept stable, and thus a thermal deformation of the base material can be suppressed.

The take-up type vacuum deposition apparatus may further include a charged particle irradiation means. The charged particle irradiation means irradiates charged particles onto the base material before the deposition.

With the take-up type vacuum deposition apparatus, adhesiveness of the base material with respect to the cooling roller can be improved. Thus, a thermal deformation of the base material can be prevented more effectively.

In the take-up type vacuum deposition apparatus, the charge capturing body may be formed of a metal mesh plate connected to a ground potential.

With the take-up type vacuum deposition apparatus, a capturing effect of the charged particles can be improved. Moreover, an increase in size of the apparatus can be avoided because a gap between the neutralization unit and the cooling roller can be effectively used.

The take-up type vacuum deposition apparatus may further include a detection means.

The detection means electrically detects a pinhole in the metallic layer deposited on the base material.

In the take-up type vacuum deposition apparatus, by providing the charge capturing body, variation in the potential of the cooling roller can be prevented. Therefore, a pinhole in the metallic layer can be stably detected by the detection means.

### DRAWINGS

FIG. 1 is a schematic structural diagram of a take-up type vacuum vapor deposition apparatus as a take-up type vacuum deposition apparatus according to an embodiment of the present invention;

FIG. 2 is a schematic cross-sectional view showing a structure of a DC bias power source in the take-up type vacuum vapor deposition apparatus of FIG. 1;

FIGS. 3A and 3B are cross-sectional views each showing a structural example of a neutralizing unit in the take-up type vacuum vapor deposition apparatus of FIG. 1; and

FIG. 4 is an enlarged view showing an internal structure of the neutralizing unit shown in FIG. 3.

### DETAILED DESCRIPTION

Hereinafter, an embodiment of the present invention will be described with reference to the drawings. In this embodiment, as an example of the take-up type vacuum deposition apparatus, a description will be given on a take-up type vacuum vapor deposition apparatus in which an evaporation source of an evaporation material is used as a deposition source, the apparatus being used for manufacturing film capacitors, for example.

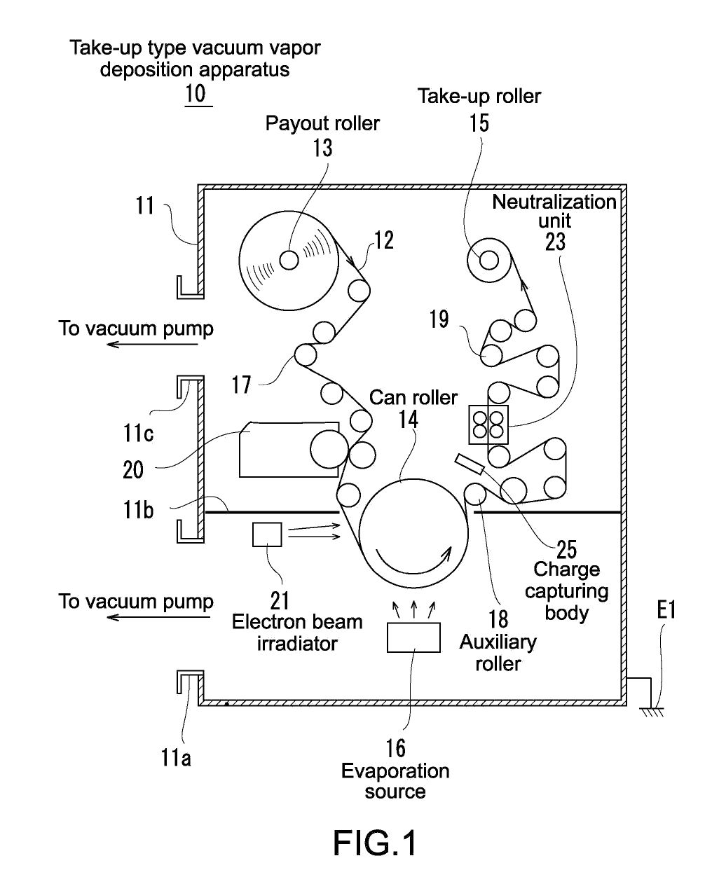

FIG. 1 is a schematic structural diagram of a take-up type vacuum vapor deposition apparatus 10 according to the embodiment of the present invention. The take-up type vacuum vapor deposition apparatus 10 includes a vacuum chamber 11, a payout roller 13 for a base material 12, a cooling can roller 14, a take-up roller 15, and an evaporation source 16 of an evaporation material.

The vacuum chamber 11 is connected to a vacuum exhaust system such as a vacuum pump (not shown) via pipe connection portions 11a and 11c, and is exhausted to reduce a pressure inside to a predetermined vacuum degree. An internal space of the vacuum chamber 11 is sectioned by a partition plate 11b into a room in which the payout roller 13, the take-up roller 15, and the like are provided, and a room in which the evaporation source 16 is provided.

The base material 12 is constituted of a long insulating film cut at a predetermined width. In this embodiment, a plastic film such as an OPP (drawn polypropylene) film, a PET (polyethylene terephthalate) film, and a PPS (polyphenylene sulfide) film is used for the base material 12, but a paper sheet and the like can be applied instead.

The base material 12 is paid out from the payout roller 13 and is taken up by the take-up roller 15 via a plurality of guide rollers 17, the can roller 14, an auxiliary roller 18, and a plurality of guide rollers 19. It should be noted that the payout roller 13 and the take-up roller 15 correspond to “transport mechanism” of the present invention.

The can roller 14 is tubular and made of metal such as iron. Inside, the can roller 14 has a cooling mechanism for causing a cooling medium to circulate, a rotary drive mechanism for rotationally driving the can roller 14, and the like. The base material 12 is wound around a circumferential surface of the can roller 14 at a predetermined holding angle. On a deposition surface on an outer surface side of the base material 12 wound around the can roller 14, an evaporation material from the evaporation source 16 is deposited to form a deposited layer, and at the same time, the base material 12 is cooled by the can roller 14.

The evaporation source 16 accommodates the evaporation material and has a mechanism for causing the evaporation material to evaporate by heating using a well-known technique such as resistance heating, induction heating, and electron beam heating. The evaporation source 16 is disposed below the can roller 14, and generates vapor of the evaporation material. The vapor of the evaporation material adheres onto the base material 12 on the can roller 14 opposed to the evaporation source 16. As a result, a deposited layer of the evaporation material is formed on the surface of the base material 12.

As the evaporation material, in addition to a metal element single body such as Al, Co, Cu, Ni, and Ti, two or more metals such as Al—Zn, Cu—Zn, and Fe—Co, or a multi-component alloy can be used. The number of evaporation source 16 is not limited to one, and a plurality of evaporation sources 16 may be provided.

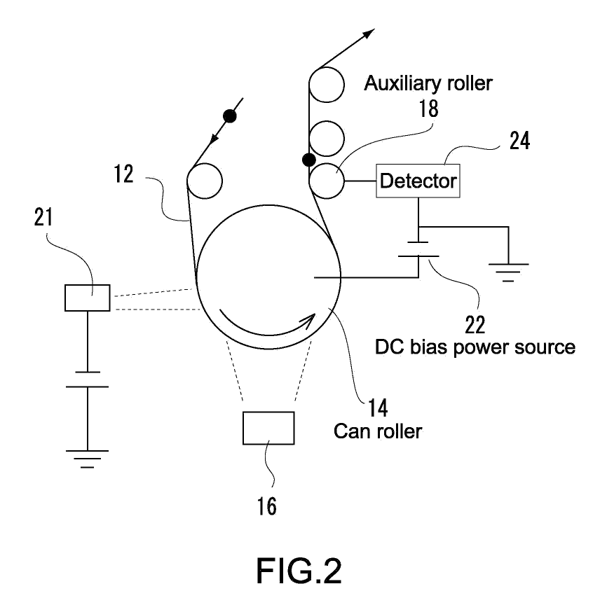

The take-up type vacuum vapor deposition apparatus 10 of this embodiment further includes a pattern formation unit 20, an electron beam irradiator 21, a DC bias power source 22 (FIG. 2), and a neutralization unit 23.

The pattern formation unit 20 forms an oil pattern (mask) for defining an evaporation area of a metallic layer with respect to the deposition surface of the base material 12. The pattern formation unit 20 is provided between the payout roller 13 and the can roller 14. The oil pattern has a shape in which the metallic layer is continuously formed on the deposition surface of the base material 12 along a longitudinal direction (traveling direction) thereof.

The electron beam irradiator 21 corresponds to “charged particle irradiation means” of the present invention, and negatively charges the base material 12 before the deposition by irradiating an electron beam as charged particles onto the base material 12. In this embodiment, the electron beam is irradiated onto the base material 12 while scanning the base material 12 in a width direction thereof to avoid a heat damage of the base material 12 due to local irradiation of the electron beam, and at the same time, to charge the base material 12 uniformly and effectively.

FIG. 2 is a diagram showing a structure of the DC bias power source 22. The DC bias power source 22 corresponds to “voltage applying means” of the present invention for applying a predetermined voltage between the can roller 14 and the auxiliary roller 18. In this embodiment, the can roller 14 is connected to a positive electrode, and the auxiliary roller 18 is connected to a negative electrode. Accordingly, the base material 12 that has been irradiated with the electron beam and negatively charged is electrically attached to the circumferential surface of the can roller 14 by electrostatic attractive force, and brought into close contact therewith. It should be noted that the DC bias power source 22 may be of a fixed-type or a variable-type.

A metal material is vapor-deposited onto the deposition surface of the base material 12 at a position immediately above the evaporation source 16. Since the metallic layer formed on the base material 12 is continuous in the longitudinal direction of the base material 12, by bringing the metallic layer on the deposition surface of the base material 12 guided by the auxiliary roller 18 into contact with a circumferential surface of the auxiliary roller 18, the base material 12 sandwiched between the metallic layer and the can roller 14 is polarized, and an electrostatic absorption power is generated between the base material 12 and the can roller 14, with the result that they are brought into close contact with each other.

In this embodiment, a pinhole detector 24 that electrically detects pinholes in the metallic layer formed on the base material 12 is connected to the DC bias power source 22. This pinhole detector 24 corresponds to “detecting means” of the present invention, and is configured to detect pinholes in the metallic layer based on, for example, a resistance change in a current flowing through the metallic film on the base material 12.

Meanwhile, the neutralization unit 23 is disposed between the can roller 14 and the take-up roller 15 and has a function of neutralizing the base material 12 that has been charged by the electron irradiation from the electron beam irradiator 21 and the voltage application from the DC bias power source 22. As an exemplary structure of the neutralization unit 23 a mechanism for neutralizing the base material 12 by carrying out ion bombard processing while causing the film 12 to pass through plasma is used.

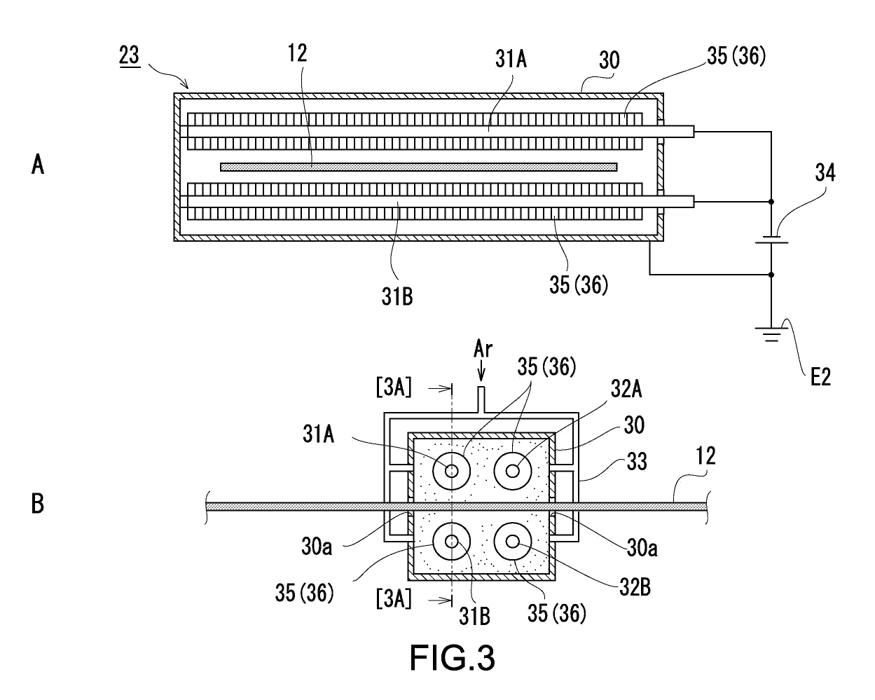

FIGS. 3 each show a structural example of the neutralization unit 23. FIG. 3A is a cross-sectional view perpendicular to the traveling direction of the base material, and FIG. 3B is a cross-sectional view parallel to the traveling direction of the base material. The neutralization unit 23 includes a metal frame 30 including slots 30a, 30b through which the base material 12 can be passed, two pairs of electrodes 31A, 31B, and 32A, 32B, opposed to each other within the frame 30 with the base material 12 being interposed therebetween, and an introduction tube 33 through which a process gas such as argon is introduced into the frame 30.

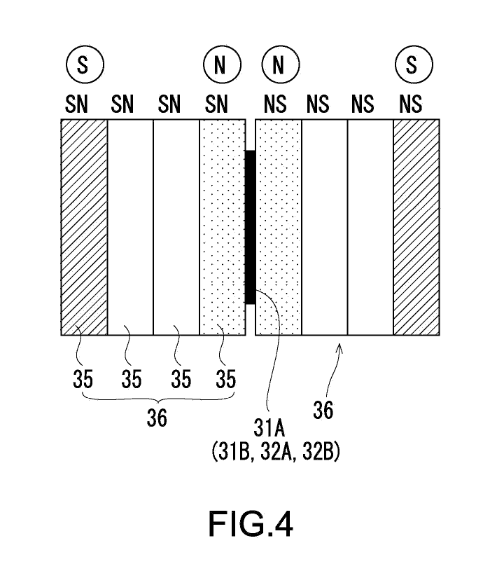

On the one hand, the frame 30 is connected to a positive electrode of a DC power source 34 and to a ground potential E2. On the other hand, each of the electrodes 31A, 31B, 32A, and 32B is a shaft-like electrode connected to a negative electrode of the DC power source 34. As shown in FIG. 4, in an outer circumferential of each of the electrodes, a plurality of sets of magnetic blocks 36, each of which constituted of a plurality of annular permanent magnet pieces 35, are mounted along an axial direction of the electrode in alternate polarities such that a pattern of SN-NS-SN-. . . is repeated.

It should be noted that each of the magnetic blocks 36 is constituted of the plurality of permanent magnet pieces 36 for facilitating adjustment of lengths among magnetic poles of the magnetic blocks 36. Each of the magnetic blocks 36 may of course be formed of a single permanent magnet material. In addition, the DC power source 34 is shown as a fixed power source, but may be a variable power source.

As described above, the neutralization unit 23 of this embodiment includes, in addition to a plasma generation source of DC bipolar discharge type as a basic structure that applies a DC voltage between the frame 30 and the electrodes 31A, 31B, 32A, and 32B to generate plasma, a magnetic field converging function (magnetron discharge) obtained by causing a magnetic field of each magnetic block 36 to be orthogonal to an electric field component between the frame and each electrode, such that the plasma is generated to be confined in a magnetic field around the electrode. In addition, the plasma is desirably of low pressure in terms of protection of the base material 12. In this case, the plasma can be easily generated at a low pressure by using the magnetron-discharge-type plasma generation source as shown in FIG. 4.

In the neutralization unit 23 having the structure as described above, electrons and charged particles such as ions in the plasma that are formed in the frame 30 leak to an outside of the frame 30 through the slot 30a provided in the frame 30 for insertion of the base material 12. The leaked charged particles float in the vacuum chamber 11 and are carried by an exhaust flow toward the can roller 14. When the charged particles reach the can roller 14, a bias potential that is applied to the can roller 14 changes, resulting in an unstable adhesiveness between the base material 12 and the can roller 14 and erroneous operations in the pinhole detection in the metallic layer by the pinhole detector 24.

In this regard, in this embodiment, a charge capturing body 25 that captures the charged particles floating from the neutralization unit 23 toward the can roller 14 is provided between the neutralization unit 23 and the can roller 14. The charge capturing body 25 prevents the charged particles leaked from the neutralization unit 23 from reaching the can roller 14 to suppress variation in the potential of the can roller 14 and keep stable electrostatic force with respect to the base material 12. Accordingly, adhesion force between the base material 12 and the can roller 14 is kept stable, with the result that a thermal deformation of the base material is prevented. Erroneous operations of the pinhole detector 24 are also be suppressed, with the result that a proper pinhole detection function is maintained.

In this embodiment, the charge capturing body 25 is constituted of a metal mesh plate. The charge capturing body 25 is fixed to an inner wall of the vacuum chamber 11 via an appropriate support member (not shown). The vacuum chamber 11 is connected to a ground potential E1. Therefore, the charge capturing body 25 is grounded via the vacuum chamber 11.

Size, shape, and the like of the mesh of the charge capturing body 25 are not particularly limited. Size, shape, and the like of the of the charge capturing body 25 are also not particularly limited as long as it is capable of capturing the charged particles floating from the neutralization unit 23 toward the can roller 14. It should be noted that the charge capturing body 25 may be constituted of a comb-like plate, a punched metal, or the like, in addition to the mesh plate. Further, a film-like or sheet-like charge capturing body may be used as long as a desired effect can be obtained.

Next, a description will be given on an operation of the take-up type vacuum vapor deposition apparatus 10 of this embodiment.

Inside the vacuum chamber 11 that is pressure-reduced to a predetermined vacuum degree, the base material 12 successively paid out from the payout roller 13 is subjected to an oil pattern (mask) formation process, an electron beam irradiation process, a vapor deposition process, and a neutralization process before being successively taken up by the take-up roller 15.

In the oil pattern formation process, an oil pattern having a predetermined shape is applied and formed on the deposition surface of the base material 12 by the pattern formation unit 20. As a mask formation method, for example, a pattern transcription method using a transcription roller that transcribes the oil pattern to the base material 12 is used. The base material 12 on which the oil pattern has been formed is wound around the can roller 14. The base material 12 is irradiated with, in the vicinity of a position at which the base material 12 starts to come into contact with the can roller 14, the electron beam from the electron beam irradiator 21 to be negatively charged in potential.

The base material 12 negatively charged by being irradiated with the electron beam is brought into close contact with, through electrostatic attractive force, the can roller 14 that is biased to a positive electric potential by the DC bias power source 22. Then, the evaporation material evaporated from the evaporation source 16 is deposited onto the deposition surface of the base material 12 to thus form a metallic layer. This metallic layer is formed in the longitudinal direction of the base material 12 to have a shape corresponding to the oil pattern.

The metallic layer formed on the base material 12 is applied with a negative electric potential by the DC bias power source 22 via the auxiliary roller 18. The metallic layer is formed successively in a longitudinal direction of the base material 12. Thus, the base material 12 wound around the can roller 14 after the deposition of the metallic layer is positively polarized on a surface on the metallic layer side and negatively polarized on the other surface on the can roller 14 side, to thus generate electrostatic absorption force between the base material 12 and the can roller 14. As a result, the base material 12 and the can roller 14 are brought into close contact with each other.

As described above, in this embodiment, before the vapor deposition of the metallic layer, the base material 12 is brought into close contact with the can roller 14 by being charged by the irradiation of the electron beam, whereas after the vapor deposition of the metallic layer, the base material 12 is brought into close contact with the can roller 14 by a bias voltage applied between the metallic layer and the can roller 14. Thus, even if partial charge (electrons) charged with respect to the base material 12 before the vapor deposition of the metallic layer is discharged to the metallic layer and lost in the vapor deposition process of the metallic layer thereafter, a part or all of the lost charge can be compensated for by applying a negative electric potential (supplying electrons) to the metallic layer from the auxiliary roller 18. Therefore, lowering of adhesion force between the base material 12 and the can roller 14 is suppressed even after the vapor deposition process, and a stable cooling effect with respect to the base material 12 can be secured before and after the vapor deposition process.

The base material 12 onto which the metallic layer has been deposited as described above is neutralized by the neutralization unit 23, and then taken up by the take-up roller 15. According to this embodiment, since the neutralization unit 23 is constituted of the DC-bipolar-discharge-type plasma generation source, one electrode of which is grounded, adjustment or fine adjustment of potentials of the electrodes 31A, 31B, 32A, and 32B with respect to a potential of the frame 30 can be carried out easily and properly, and thus a neutralization effect can be improved.

In other words, if the neutralization unit 23 is not connected to the ground potential, a potential of the whole unit becomes a floating state and a reference potential is slightly shifted, and therefore a high neutralizing effect cannot be obtained. However, by connecting one electrode (frame 30) of the neutralization unit 23 to the reference potential E2, it becomes possible to adjust the DC voltage 34 to carry out adjustment of the neutralization from several volts to several tens of volts. Accordingly, a withstanding voltage of the base material 12 can be suppressed to several volts, with the result that it becomes possible to secure a stable take up operation of the base material 12, and at the same time, to prevent wrinkles caused during winding due to the charge. Moreover, it becomes possible to realize proper assembly of film capacitor products.

Further, according to this embodiment, since the charge capturing body 25 is provided between the neutralizing unit 23 and the can roller 14, the charged particles leaked from the neutralizing unit 23 can be prevented from reaching the can roller 14 to suppress variation in the potential of the can roller 14. In particular, in a case where the charged particles are electrons, it is possible to effectively prevent lowering of the potential of the can roller 14 caused by the electrons reached the can roller 14 and lowering of adhesion force with respect to the base material 12. Thus, the adhesion force between the can roller 14 and the base material 12 is kept stable, with the result that it becomes possible to effectively suppress a thermal deformation of the base material.

Moreover, by providing the charge capturing body 25, variation on the potential of the can roller 14 due to the charged particles leaked from the neutralizing unit 23 can be prevented. Thus, it is possible to secure a proper operation of the pinhole detector 24 to carry out highly reliable pinhole detection in the metallic layer.

According to an experiment by the inventors, when the number of pinhole detection times per a base material of 100 meter was measured by the pinhole detector 24 having above-described structure, the number of pinhole detection times was, 141 in a case where the charge capturing body 25 was not provided, while only one in a case where the charge capturing body 25 is provided. This result shows a fact that an influence of the charged particles leaked from the neutralization unit 23 can be effectively eliminated by the charge capturing body 25, rather than an occurrence frequency of pinholes.

Further, according to this embodiment, the charge capturing particles 25 is constituted of the metal mesh plate connected to the ground potential. Thus, a capturing effect of charged particles can be improved, and at the same time, an increase in size of the apparatus can be avoided because a gap between the neutralizing unit 23 and the can roller 14 can be effectively used.

Although the embodiment of the present invention has been described above, the present invention is of course not limited thereto, and can be variously modified based on the technical idea of the present invention.

For example, in the above embodiment, the base material 12 is negatively charged by being irradiated with the electron beam, but the base material may instead be positively charged by being irradiated with ions. In this case, the polarity of the bias that is applied to the can roller 14 and the auxiliary roller 18 is inverted with respect to the polarity in the above embodiment (can roller 14 becomes negative electrode, and auxiliary roller 18 becomes positive electrode).

In addition, in the above embodiment, the example in which the vacuum vapor deposition method is used as the deposition method of the metallic layer is described. However, the present invention is of course not limited thereto, and other deposition methods using other deposition means for depositing the metallic layer, such as a sputtering method and various CVD methods, can be employed.

1. A take-up type vacuum deposition apparatus for depositing a metallic layer on a base material having insulation property, comprising:
a vacuum chamber;
a transport mechanism that transports the base material inside the vacuum chamber;
a cooling roller that cools the base material by coming into close contact with the base material;
a deposition means provided opposed to the cooling roller for depositing the metallic layer on the base material;
an auxiliary roller that guides traveling of the base material by coming into contact with a deposition surface of the base material;
a voltage application unit that applies a DC voltage between the cooling roller and the auxiliary roller;
a neutralization unit that neutralizes the base material by a plasma treatment in a metal frame including a slot through which the base material is passed; and
a charge capturing body provided between the cooling roller and the neutralization unit that captures charged particles floating from the neutralization unit toward the cooling roller.

2. The take-up type vacuum deposition apparatus according to claim 1, further comprising:
a charged particle irradiation means for irradiating charged particles onto the base material before the deposition.

3. The take-up type vacuum deposition apparatus according to claim 1,
wherein the charge capturing body is constituted of a metal mesh plate connected to a ground potential.

4. The take-up type vacuum vapor deposition apparatus according to claim 1, further comprising:
a detection means for electrically detecting a pinhole in the metallic layer deposited on the base material.
